(19) United States
(12) Patent Application Publication
(10) Pub. No.: US 2026/0026174 A1
(43) Pub. Date: Jan. 22, 2026

(54) LIGHT-EMITTING DIODE STRUCTURE AND MANUFACTURING METHOD THEREOF

(71) Applicant: GUANGZHOU LUXVISIONS INNOVATION TECHNOLOGY LIMITED, Guangzhou City (CN)

(72) Inventors: Yi-Chih Lai, Guangzhou City (CN); Wei-Han Wu, Guangzhou City (CN)

(73) Assignee: GUANGZHOU LUXVISIONS INNOVATION TECHNOLOGY LIMITED, Guangzhou City (CN)

(21) Appl. No.: 19/096,739

(22) Filed: Apr. 1, 2025

Related U.S. Application Data
(60) Provisional application No. 63/672,220, filed on Jul. 16, 2024.

(30) Foreign Application Priority Data
Nov. 12, 2024 (CN) 202411611514.0

(51) Int. Cl. H10H 29/851; H10H 29/01; H10H 29/80; H10H 29/856

(52) U.S. Cl. CPC H10H 29/8515; H10H 29/034; H10H 29/0361; H10H 29/0363; H10H 29/842; H10H 29/856

(57) ABSTRACT

A light-emitting diode structure and a manufacturing method thereof are provided. The light-emitting diode structure includes a substrate, multiple light-emitting diode units, and a reflective layer. The light-emitting diode units are arranged in arrays on the substrate. Each of the light-emitting diode units includes a light-emitting diode chip, a wavelength conversion layer, and a short-pass filter coating. The light-emitting diode chip is disposed on the substrate in a flip-chip manner. The wavelength conversion layer is disposed on the light-emitting diode chip. The short-pass filter coating is disposed between the wavelength conversion layer and the light-emitting diode chip. The reflective layer is filled in a gap between the light-emitting diode chips of the light-emitting diode units and is disposed on a side surface of the light-emitting diode chips.

### CROSS-REFERENCE TO RELATED APPLICATION

This application claims the priority benefit of U.S. provisional application Ser. No. 63/672,220, filed on Jul. 16, 2024 and China application serial no. 202411611514.0, filed on Nov. 12, 2024. The entirety of each of the above-mentioned patent applications is hereby incorporated by reference herein and made a part of this specification.

### BACKGROUND

### Technical Field

The disclosure relates to a light-emitting structure and a manufacturing method thereof, and in particular to a light-emitting diode structure and a manufacturing method thereof.

### Description of Related Art

Existing white light-emitting diodes are formed by covering a blue light-emitting diode chip with yellow phosphor. When the blue light emitted by the blue light-emitting diode chip irradiates the yellow phosphor, a portion of the blue light excites the yellow phosphor to generate yellow light. In other words, the yellow phosphor converts a portion of the blue light into yellow light. The remaining blue light that is not converted into yellow light by the yellow phosphor mixes with the yellow light to form white light.

However, when the blue light excites the yellow phosphor to generate yellow light, although a portion of the yellow light is transmitted in a direction away from the blue light-emitting diode chip to form effective light, another portion of the yellow light is transmitted toward the blue light-emitting diode chip, resulting in a loss of light.

In addition, the yellow phosphor is mixed into the encapsulation resin and then covered on the blue light-emitting diode chip. Since the refractive index of the blue light-emitting diode chip is different from that of the encapsulation resin, Fresnel loss occurs when the blue light is transmitted to the interface between the blue light-emitting diode chip and the encapsulation resin. As a result, the blue light is reflected into the interior of the blue light-emitting diode chip at the interface, causing light intensity loss.

Furthermore, in existing multi-light source modules, the process involves packaging individual light-emitting diodes and then performing placement to arrange the light-emitting diodes on a substrate. However, this process prevents the light-emitting diodes from being arranged compactly, making it difficult to reduce the spacing between adjacent light-emitting diodes and the overall manufacturing cost of the module.

### SUMMARY

The disclosure relates to a light-emitting diode structure that effectively reduces light intensity loss and improves light efficiency while having a compact structure and lower manufacturing cost.

The disclosure also relates to a manufacturing method of a light-emitting diode structure, which enables the fabrication of a light-emitting diode structure with high light efficiency, a compact structure, and lower manufacturing cost.

In an embodiment of the disclosure, a light-emitting diode structure is provided. The light-emitting diode structure includes a substrate, a plurality of light-emitting diode units, and a reflective layer. The plurality of light-emitting diode units are arranged in an array on the substrate. Each of the plurality of light-emitting diode units includes a light-emitting diode chip, a wavelength conversion layer, and a short-pass filter coating. The light-emitting diode chip is disposed on the substrate in a flip-chip manner and is used to emit a first light beam. The wavelength conversion layer is disposed on the light-emitting diode chip and is used to convert a portion of the first light beam into a second light beam. A wavelength of the first light beam is less than a wavelength of the second light beam. The short-pass filter coating is disposed between the wavelength conversion layer and the light-emitting diode chip, allowing the first light beam to pass through and reflecting the second light beam. The reflective layer is filled in a gap between the plurality of light-emitting diode chips of the plurality of light-emitting diode units and is disposed on a side surface of the plurality of light-emitting diode chips.

In an embodiment of the disclosure, a manufacturing method of a light-emitting diode structure is provided. The manufacturing method includes the following steps. A plurality of light-emitting diode chips are provided. Each of the plurality of light-emitting diode chips has an electrode, and a short-pass filter coating is disposed on a side of the light-emitting diode chip facing away from the electrode. The plurality of light-emitting diode chips are disposed on a first temporary substrate, with the electrode facing away from the first temporary substrate. A reflective layer is filled in a gap between the plurality of light-emitting diode chips and on a side surface of the plurality of light-emitting diode chips. The plurality of light-emitting diode chips are separated along with the reflective layer from the first temporary substrate. The plurality of light-emitting diode chips along with the reflective layer are disposed on a second temporary substrate, with the electrode facing the second temporary substrate. The plurality of light-emitting diode chips are covered with a wavelength conversion layer. The plurality of light-emitting diode chips along with the reflective layer and the wavelength conversion layer are separated from the second temporary substrate. The plurality of light-emitting diode chips along with the reflective layer and the wavelength conversion layer are disposed on a substrate.

In an embodiment of the disclosure, a manufacturing method of a light-emitting diode structure is provided. The manufacturing method includes the following steps. A plurality of light-emitting diode chips are provided. Each of the plurality of light-emitting diode chips has an electrode, and a short-pass filter coating is disposed on a side of the light-emitting diode chip facing away from the electrode. The plurality of light-emitting diode chips are disposed on a substrate, with the electrode facing the substrate. A reflective layer is filled in a gap between the plurality of light-emitting diode chips and on a side surface of the plurality of light-emitting diode chips. The plurality of light-emitting diode chips are covered with a wavelength conversion layer.

In the light-emitting diode structure and the manufacturing method thereof according to the embodiments of the disclosure, the short-pass filter coating allows the first light beam emitted by the light-emitting diode chip to pass through and reflects the second light beam from the wavelength conversion layer. As a result, loss of the second light beam transmitted into the interior of the light-emitting diode chip may be effectively reduced, thereby improving the light efficiency of the light-emitting diode structure. In addition, in the light-emitting diode structure and the manufacturing method thereof according to the embodiments of the disclosure, the reflective layer is filled in the gap between the plurality of light-emitting diode chips of the plurality of light-emitting diode units and is disposed on a side surface of the plurality of light-emitting diode chips to achieve integrated packaging of the light-emitting diode chips. This configuration reduces the spacing between adjacent light-emitting diode chips, resulting in a compact structure and effectively lowering the manufacturing cost of the light-emitting diode structure.

### BRIEF DESCRIPTION OF THE DRAWINGS

FIG. 1A is a cross-sectional schematic diagram of a light-emitting diode structure according to an embodiment of the disclosure.

FIG. 1B is a top view schematic diagram of the light-emitting diode structure in FIG. 1A.

FIG. 1C illustrates a cross-sectional schematic diagram of a light-emitting diode unit in FIG. 1A.

FIG. 1D illustrates one light-emitting diode chip in FIG. 1A.

FIG. 2 is a spectral diagram of the first light beam in FIG. 1.

FIG. 3 is a spectral diagram of the first light beam and the second light beam of the light-emitting diode structure in FIG. 1.

FIG. 4A illustrates a detailed multilayer structure of the short-pass filter coating in FIG. 1A.

FIG. 4B is a spectral diagram showing the transmittance of the short-pass filter coating in FIG. 1A under multiple different incident angles.

FIG. 5 is a percentage distribution diagram of light intensity at different light-emitting angles for the light-emitting diode structure in FIG. 1A and a light-emitting diode structure without the short-pass filter coating.

FIG. 6 is a cross-sectional schematic diagram of a light-emitting diode structure according to another embodiment of the disclosure.

FIG. 7A is a cross-sectional schematic diagram of a light-emitting diode structure according to yet another embodiment of the disclosure.

FIG. 7B is a top view schematic diagram of the light-emitting diode structure in FIG. 7A.

FIG. 8A is a cross-sectional schematic diagram of a light-emitting diode structure according to still another embodiment of the disclosure.

FIG. 8B is a top view schematic diagram of the light-emitting diode structure in FIG. 8A.

FIG. 9 is a cross-sectional schematic diagram of a light-emitting diode structure according to another embodiment of the disclosure.

FIGS. 10A, 10B, and 10C illustrate front view schematic diagrams of different light-emitting diode units in the light-emitting diode structure in FIG. 9 when illuminated.

FIGS. 11A to 11I are cross-sectional schematic diagrams illustrating the process flow of a manufacturing method of a light-emitting diode structure according to an embodiment of the disclosure.

FIGS. 12A to 12C are cross-sectional schematic diagrams illustrating the process flow of a manufacturing method of a light-emitting diode structure according to another embodiment of the disclosure.

FIG. 13 is a cross-sectional schematic diagram illustrating one step of a manufacturing method of a light-emitting diode structure according to yet another embodiment of the disclosure.

FIGS. 14A to 14C are cross-sectional schematic diagrams illustrating part of the process flow of a manufacturing method of a light-emitting diode structure according to still another embodiment of the disclosure.

### DESCRIPTION OF THE EMBODIMENTS

The exemplary embodiments of the disclosure will now be described in detail with reference to the accompanying drawings. Wherever possible, the same reference numerals are used in the drawings and descriptions to represent the same or similar parts.

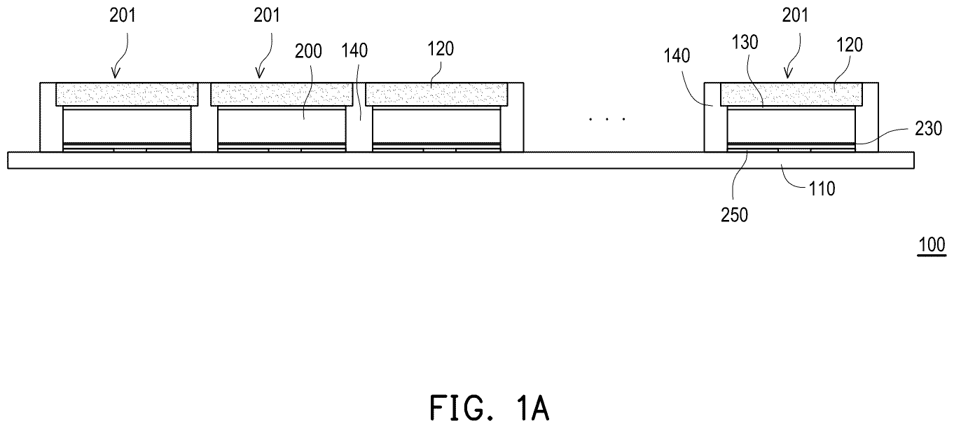

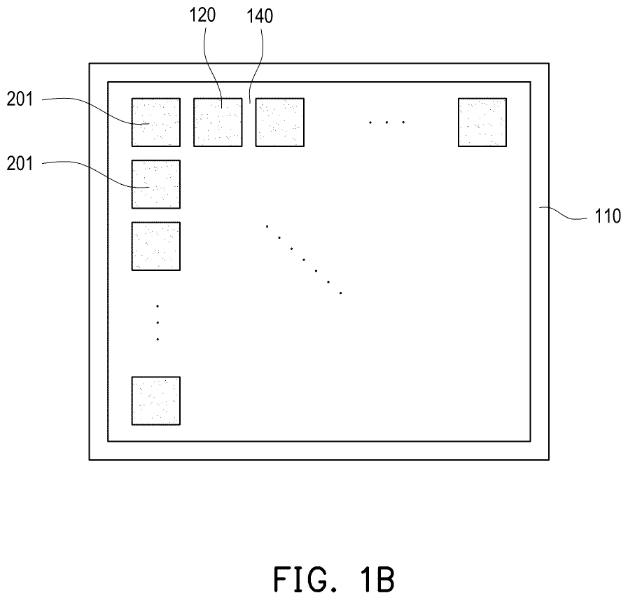

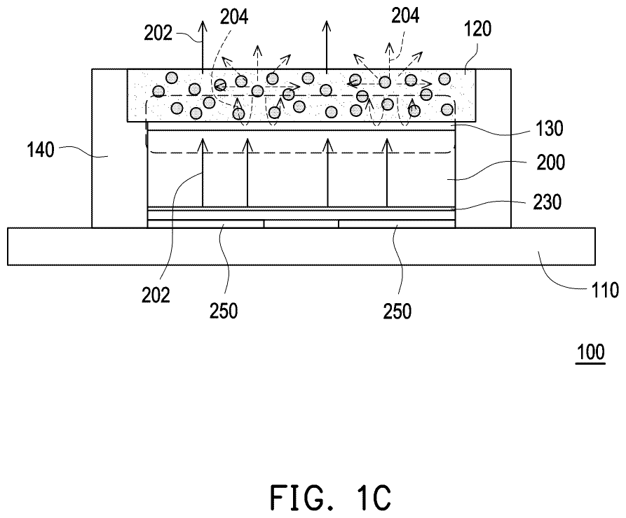

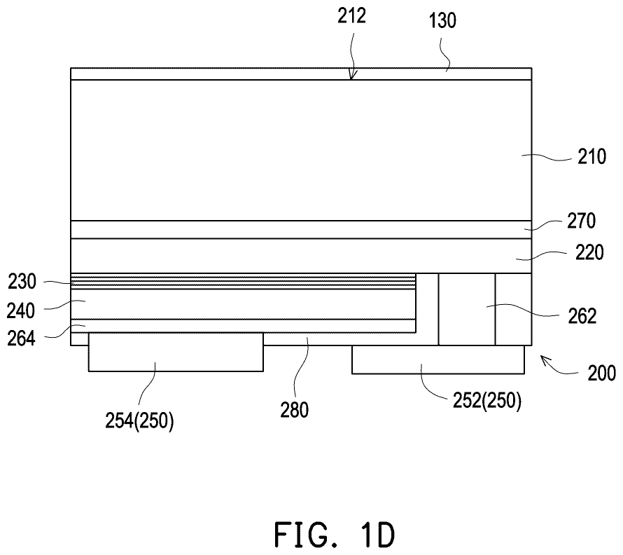

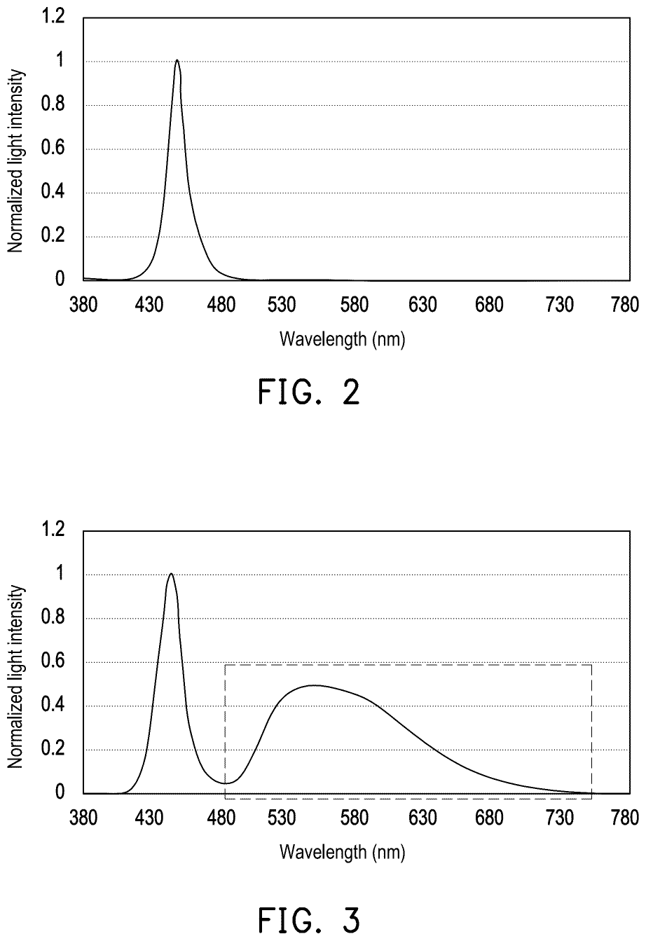

FIG. 1A is a cross-sectional schematic diagram of a light-emitting diode structure according to an embodiment of the disclosure. FIG. 1B is a top view schematic diagram of the light-emitting diode structure in FIG. 1A. FIG. 1C illustrates a cross-sectional schematic diagram of a light-emitting diode unit in FIG. 1A. FIG. 1D illustrates one light-emitting diode chip in FIG. 1A. FIG. 2 is a spectral diagram of the first light beam in FIG. 1. FIG. 3 is a spectral diagram of the first light beam and the second light beam of the light-emitting diode structure in FIG. 1. Referring to FIGS. 1A to 1D, FIG. 2, and FIG. 3, a light-emitting diode structure 100 in this embodiment includes a substrate 110, a plurality of light-emitting diode units 201, and a reflective layer 140. The plurality of light-emitting diode units 201 are arranged in an array on the substrate 110. Each of the plurality of light-emitting diode units 201 includes a light-emitting diode chip 200, a wavelength conversion layer 120, and a short-pass filter coating 130. The light-emitting diode chip 200 is disposed on the substrate 110 in a flip-chip manner and is used to emit a first light beam 202. The wavelength conversion layer 120 is disposed on the light-emitting diode chip 200 and is used to convert a portion of the first light beam 202 into a second light beam 204, wherein a wavelength of the first light beam 202 is less than a wavelength of the second light beam 204. The wavelength conversion layer 120 may be, for example, a phosphor layer or a quantum dot layer. In this embodiment, the first light beam 202 may be, for example, blue light, and the second light beam 204 may be, for example, yellow light, red light, or a combination thereof. As shown in FIG. 2 and FIG. 3, FIG. 2 illustrates the spectrum of the first light beam 202. The left side outside the dashed box in FIG. 3 illustrates the spectrum of the first light beam 202, while the spectrum inside the dashed box represents the spectrum of the second light beam 204. In FIG. 3, the spectrum inside the dashed box represents the second light beam 204 as yellow light. In this case, the wavelength conversion layer 120 contains yellow phosphor or yellow quantum dots.

The short-pass filter coating 130 is disposed between the wavelength conversion layer 120 and the light-emitting diode chip 200, allowing the first light beam 202 to pass through and reflecting the second light beam 204. In this embodiment, the short-pass filter coating 130 is disposed on a side of the light-emitting diode chip 200 away from the substrate 110.

Furthermore, in this embodiment, the wavelength conversion layer 120 is disposed on a side of the short-pass filter coating 130 away from the substrate 110. The reflective layer 140 is filled in a gap between the plurality of light-emitting diode chips 200 of the plurality of light-emitting diode units 201 and is disposed on a side surface of the plurality of light-emitting diode chips 200. In this embodiment, the reflective layer 140 covers a side surface of the wavelength conversion layer 120, as shown in FIG. 1A and FIG. 1C.

In this embodiment, the light-emitting diode chip 200 includes a growth substrate 210, a first type semiconductor layer 220, a light-emitting layer 230, a second type semiconductor layer 240, and an electrode 250. The short-pass filter coating 130 is disposed on a surface 212 of the growth substrate 210 that faces away from the substrate 110 (the substrate 110 is shown in FIG.

1A and is located below the light-emitting diode chip 200 in FIG. 1D). The first type semiconductor layer 220 is disposed between the growth substrate 210 and the substrate 110. The light-emitting layer 230 is disposed between the first type semiconductor layer 220 and the substrate 110. The second type semiconductor layer 240 is disposed between the light-emitting layer 230 and the substrate 110. The electrode 250 (as shown in FIG. 1A and FIG. 1D) is disposed between the second type semiconductor layer 240 and the substrate 110 and is electrically connected to the substrate 110.

In this embodiment, the electrode 250 may be divided into a first electrode 252 and a second electrode 254. The first electrode 252 may be electrically connected to the first type semiconductor layer 220 via a conductive via 262, while the second electrode 254 may be electrically connected to the second type semiconductor layer 240 via a conductive layer 264. Furthermore, a buffer layer 270 may be disposed between the growth substrate 210 and the first type semiconductor layer 220. In this embodiment, the first type and second type semiconductor layers are N-type and P-type, respectively. However, in other embodiments, the first type and second type semiconductor layers may be P-type and N-type, respectively. Additionally, the light-emitting diode chip 200 may include an insulating layer 280, which covers the second type semiconductor layer 240 and the light-emitting layer 230 but exposes the second electrode 254, and isolates the light-emitting layer 230 from the conductive via 262 and the second type semiconductor layer 240 from the conductive via 262.

In the light-emitting diode structure 100 in this embodiment, since the short-pass filter coating 130 allows the first light beam 202 emitted by the light-emitting diode chip 200 to pass through and reflects the second light beam 204 from the wavelength conversion layer 120, the loss of the second light beam 204 transmitted into the interior of the light-emitting diode chip 200 may be effectively reduced, thereby improving the light efficiency of the light-emitting diode structure 100. Specifically, after passing through the short-pass filter coating 130, the first light beam 202 emitted by the light-emitting diode chip 200 is transmitted to the wavelength conversion layer 120. The wavelength conversion layer 120 converts a portion of the first light beam 202 into the second light beam 204. At this point, the second light beam 204 is transmitted in all directions. The short-pass filter coating 130 reflects the second light beam 204 that is transmitted in the direction of the substrate 110, preventing the second light beam 204 from being transmitted into the interior of the light-emitting diode chip 200 and causing light intensity loss. The short-pass filter coating 130 also directs the second light beam 204 in a direction away from the substrate 110 to form effective light. In this way, the light efficiency of the light-emitting diode structure 100 may be effectively improved. On the other hand, the short-pass filter coating 130 has an anti-reflective effect on the first light beam 202, allowing a greater proportion of the first light beam 202 to pass through the short-pass filter coating 130 and be transmitted to the wavelength conversion layer 120. This effectively reduces interface reflection, thereby significantly improving light efficiency.

Furthermore, in the light-emitting diode structure 100 in this embodiment, since the reflective layer 140 is filled in the gap between the plurality of light-emitting diode chips 200 of the plurality of light-emitting diode units 201 and is disposed on a side surface of the plurality of light-emitting diode chips 200 to achieve integrated packaging, the spacing between adjacent light-emitting diode chips 200 may be reduced, resulting in a compact structure. This configuration also effectively lowers the manufacturing cost of the light-emitting diode structure 100.

In an embodiment, the material of the reflective layer 140 may include resin and scattering particles incorporated into the resin. The resin may be, for example, epoxy resin, silicone resin, polymethyl methacrylate, ultraviolet glue (UV glue), or photoresist. The scattering particles may be made of, for example, titanium dioxide, silicon dioxide, or boron nitride. The material of the wavelength conversion layer 120 may include resin or glass and phosphor incorporated into the resin or glass. The resin may be, for example, epoxy resin, silicone resin, polymethyl methacrylate, ultraviolet glue, or photoresist. The glass may be, for example, silicate glass, soda-lime glass, borosilicate glass, or lead glass. The phosphor may be, for example, silicate phosphor, nitride phosphor, yttrium aluminum garnet (YAG) phosphor, fluorosilicate potassium phosphor, aluminate phosphor, α-silicon aluminum oxynitride (alpha-SiAlON) phosphor, or β-silicon aluminum oxynitride (beta-SiAION) phosphor. The substrate 110 may be, for example, a printed circuit board (PCB), a metal core printed circuit board (MCPCB), a ceramic substrate, a plastic leaded chip carrier (PLCC), or a glass substrate. The material of the electrode 250 may be metal or alloy. The metal may be, for example, gold, tin, silver, copper, or a combination thereof. The alloy may be, for example, gold-tin alloy or another alloy.

In an embodiment, the material of the growth substrate 210 includes silicon (Si), silicon carbide (SiC), gallium nitride (GaN), sapphire, zinc oxide (ZnO), gallium arsenide (GaAs), or gallium phosphide (GaP). The material of the buffer layer 270 may be, for example, gallium nitride, aluminum nitride (AlN), or gallium arsenide. The first type semiconductor layer 220 may be, for example, N-type GaN, AlN, GaAs, or GaP. The second type semiconductor layer 240 may be, for example, P-type GaN, AlN, GaAs, or GaP. The material of the light-emitting layer 230 may be, for example, alternately stacked GaN and AlGaN, alternately stacked GaN and InGaN, alternately stacked GaP and AlGaInP, alternately stacked GaP and GaAs, alternately stacked GaAs and AlGaAs, or alternately stacked GaAs and GaAsP. The material of the conductive layer 264 may be, for example, gallium phosphide, indium tin oxide, or nickel. The material of the insulating layer 280 may be, for example, silicon dioxide, silicon nitride, aluminum oxide, titanium dioxide, zinc oxide, or chromium oxide.

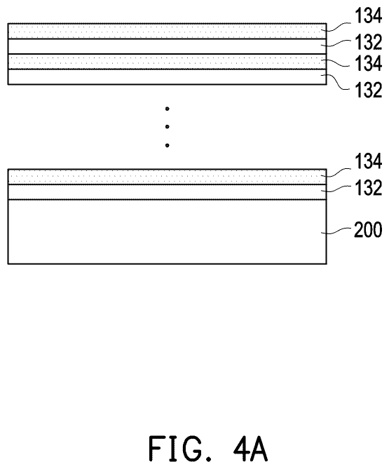

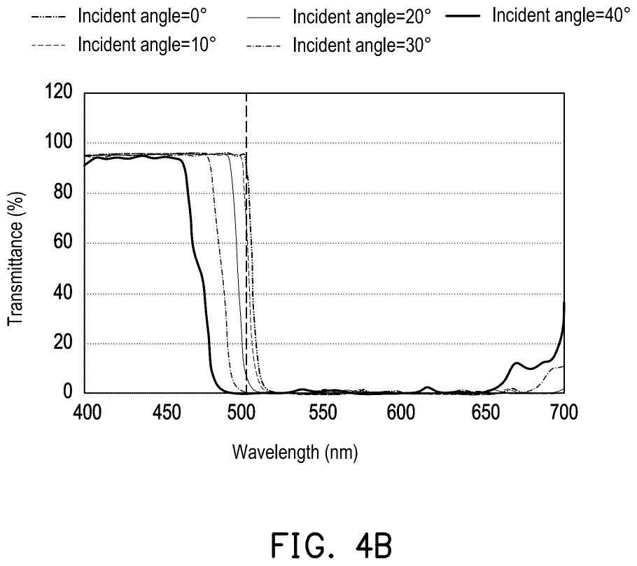

FIG. 4A illustrates a detailed multilayer structure of the short-pass filter coating in FIG. 1A, while FIG. 4B is a spectral diagram showing the transmittance of the short-pass filter coating in FIG. 1A under multiple different incident angles. Referring to FIGS. 1A, 1D, and 4A, in this embodiment, the short-pass filter coating 130 includes a plurality of low refractive index layers 132 and a plurality of high refractive index layers 134, which are alternately stacked on the light-emitting diode chip 200. The refractive index of the high refractive index layers 134 is greater than the refractive index of the low refractive index layers 132. In this embodiment, the difference between the refractive index of the high refractive index layers 134 and the refractive index of the low refractive index layers 132 is greater than 0.5. In an embodiment, the low refractive index layers 132 are made of tantalum pentoxide, and the high refractive index layers 134 are made of silicon dioxide. However, the disclosure is not limited thereto. The material of the short-pass filter coating 130 may be metal or a dielectric material. The metal may be any combination of gold, tin, silver, and aluminum, while the dielectric material may be any combination of silicon dioxide, tantalum pentoxide, and silicon. In this embodiment, referring to FIG. 4B, in terms of the transmittance spectrum at an incident angle of 0 degrees (i.e., along the optical axis direction of the light-emitting diode structure 100), the transmittance of the short-pass filter coating 130 for light with a wavelength less than 500 nanometers (nm) is greater than 90%, while the transmittance of the short-pass filter coating 130 for light with a wavelength greater than 500 nanometers is less than 5%. In an embodiment, the total number of the low refractive index layers 132 and the high refractive index layers 134 is less than 500 layers, and the thickness of each individual low refractive index layer 132 and high refractive index layer 134 is approximately 0.1 nanometers to 500 nanometers.

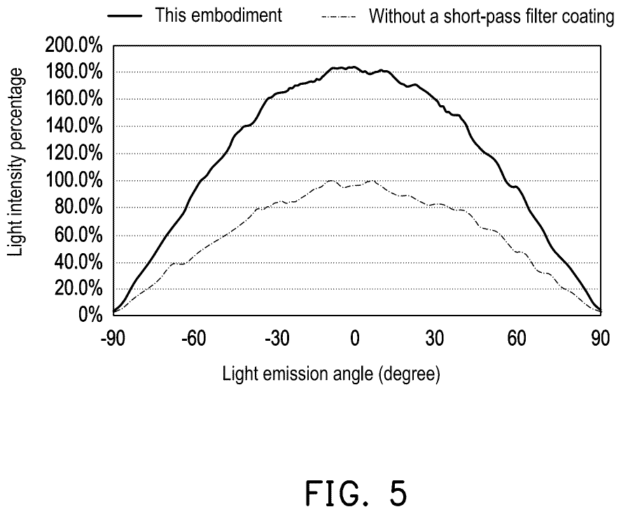

FIG. 5 is a percentage distribution diagram of light intensity at different light-emitting angles for the light-emitting diode structure in FIG. 1A and a light-emitting diode structure without the short-pass filter coating. Referring to FIGS. 1A and 5, the curve labeled “this embodiment” represents the curve of the light-emitting diode structure 100 in FIG. 1A, while the curve labeled “without a short-pass filter coating” represents the curve of the light-emitting diode structure 100 in FIG. 1A after removing the short-pass filter coating 130 and directly forming the wavelength conversion layer 120 on the light-emitting diode chip 200. This structure is hereinafter referred to as the “light-emitting diode structure without the short-pass filter coating.” In FIG. 5, the direction at a light-emitting angle of 0 degrees refers to the optical axis direction of the light-emitting diode structure. The maximum light intensity at different light-emitting angles in the light-emitting diode structure without the short-pass filter coating is defined as 100% light intensity percentage. As shown in FIG. 5, the light-emitting diode structure 100 in this embodiment in FIG. 1A may enhance light intensity by 80%. This demonstrates that the light-emitting diode structure 100 in this embodiment may effectively improve light efficiency.

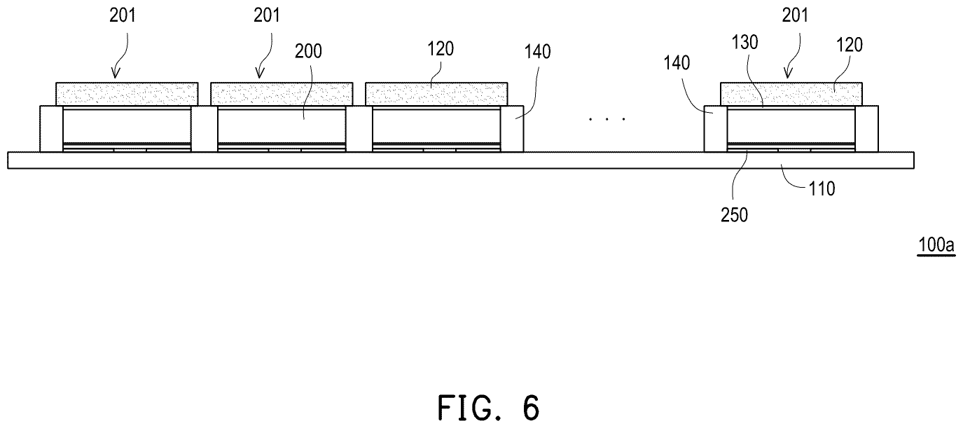

FIG. 6 is a cross-sectional schematic diagram of a light-emitting diode structure according to another embodiment of the disclosure. Referring to FIG. 6, a light-emitting diode structure 100a in this embodiment is similar to the light-emitting diode structure 100 in FIG. 1A, with the primary difference being that in the light-emitting diode structure 100a in this embodiment, the wavelength conversion layer 120 is disposed on a portion of the top surface of the reflective layer 140.

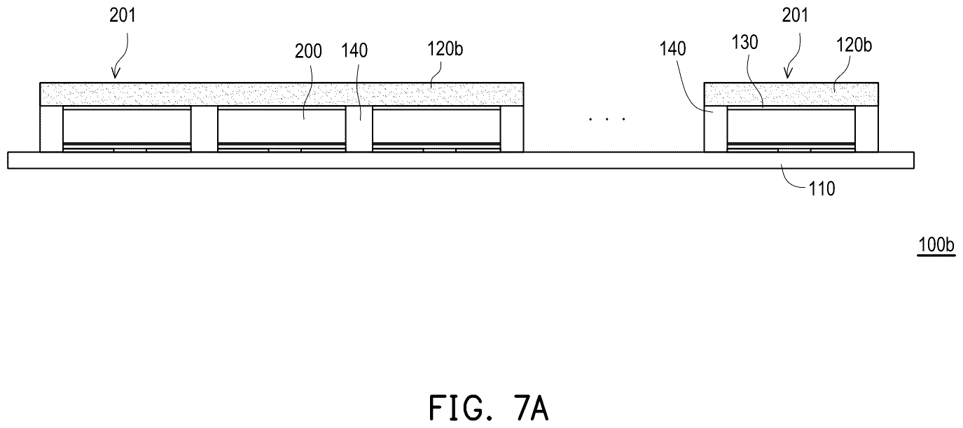

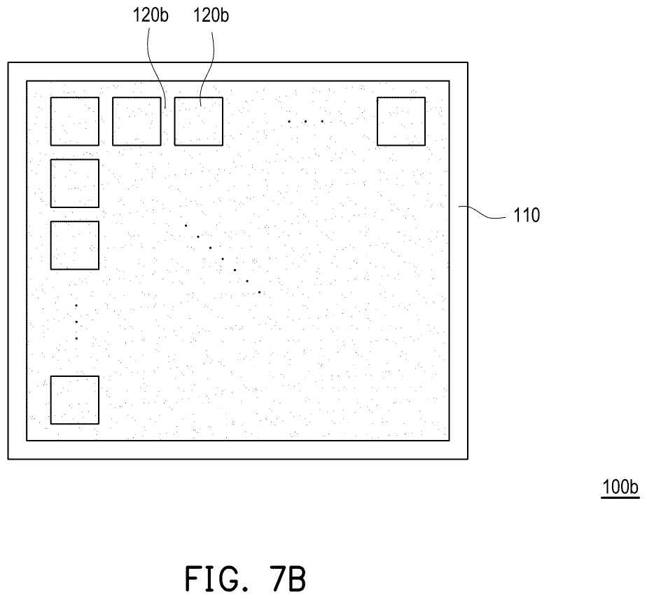

FIG. 7A is a cross-sectional schematic diagram of a light-emitting diode structure according to yet another embodiment of the disclosure, and FIG. 7B is a top view schematic diagram of the light-emitting diode structure in FIG. 7A. Referring to FIGS. 7A and 7B, a light-emitting diode structure 100b in this embodiment is similar to the light-emitting diode structure 100 in FIG. 1A, with the primary difference being that in the light-emitting diode structure 100b in this embodiment, a wavelength conversion layer 120b covers the top surface of the reflective layer 140.

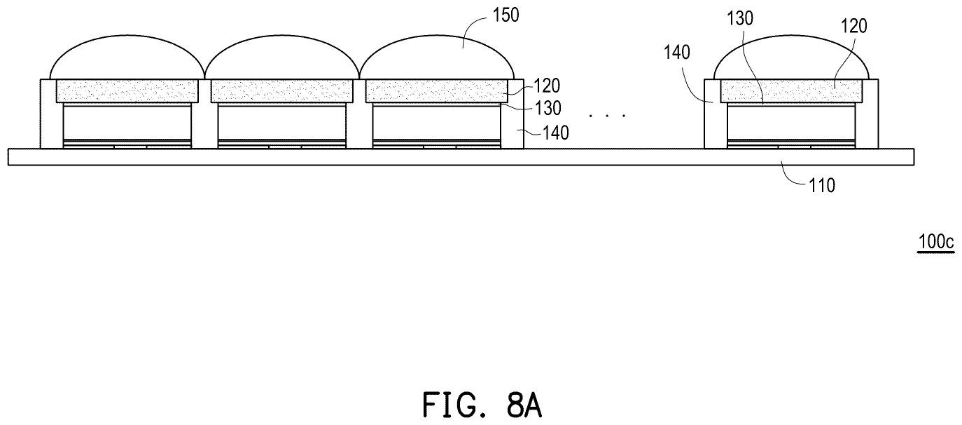

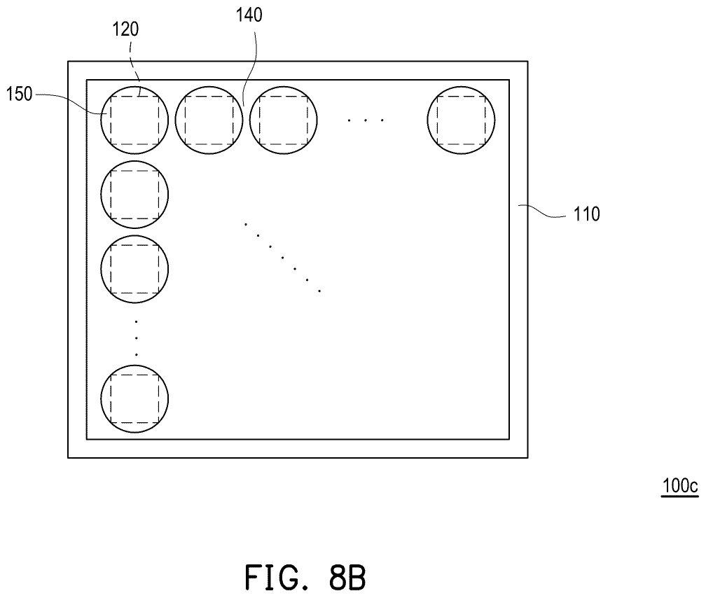

FIG. 8A is a cross-sectional schematic diagram of a light-emitting diode structure according to still another embodiment of the disclosure, and FIG. 8B is a top view schematic diagram of the light-emitting diode structure in FIG. 8A. Referring to FIGS. 8A and 8B, a light-emitting diode structure 100c in this embodiment is similar to the light-emitting diode structure 100 in FIG. 1A, with the primary difference being that the light-emitting diode structure 100c in this embodiment further includes a lens 150, which is disposed on the wavelength conversion layer 120.

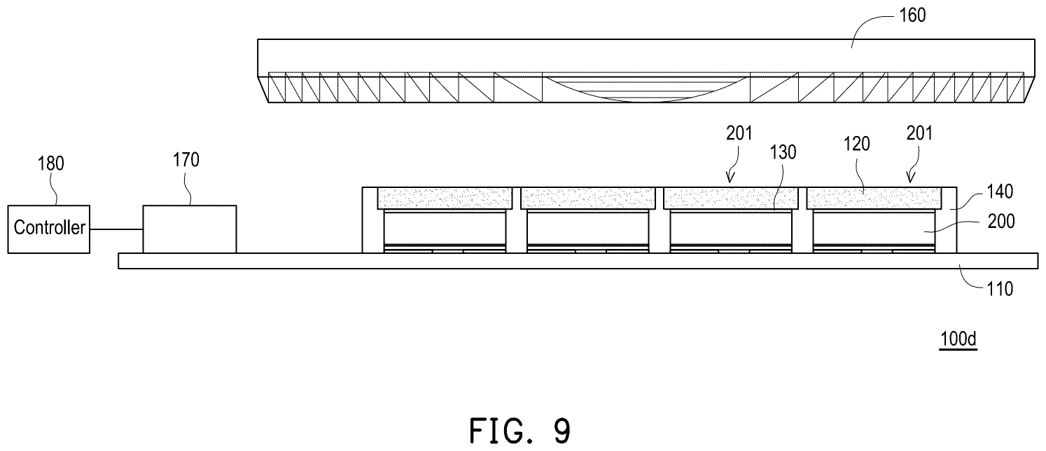

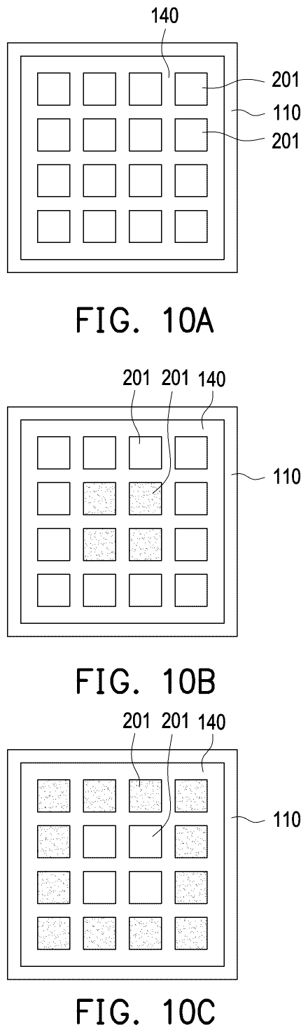

FIG. 9 is a cross-sectional schematic diagram of a light-emitting diode structure according to another embodiment of the disclosure, and FIGS. 10A, 10B, and 10C illustrate front view schematic diagrams of different light-emitting diode units in the light-emitting diode structure in FIG. 9 when illuminated. Referring to FIG. 9 and FIGS. 10A to 10C, a light-emitting diode structure 100d in this embodiment is similar to the light-emitting diode structure 100 in FIG. 1A, with the differences described as follows. The light-emitting diode structure 100d in this embodiment further includes a projection lens 160, which is disposed above the light-emitting diode units 201. In this embodiment, the light-emitting diode structure 100d further includes a driver 170, which is electrically connected to the light-emitting diode units 201 and is used to independently control the light-emitting diode units 201. The driver 170 is used to receive a control signal provided by a controller 180 and regulate the light-emitting diode units 201 so that different illuminance distributions are projected into space through the projection lens 160. For example, FIG. 10A illustrates a case where all of the light-emitting diode units 201 are illuminated. FIG. 10B illustrates a case where the peripheral light-emitting diode units 201 are illuminated while the central light-emitting diode units 201 are not illuminated. FIG. 10C illustrates a case where the peripheral light-emitting diode units 201 are not illuminated while the central light-emitting diode units 201 are illuminated. In FIGS. 10A, 10B, and 10C, the light-emitting regions of the illuminated light-emitting diode units 201 correspond to the distribution areas of the light spots projected into space by the projection lens 160, thereby forming different light spot distribution patterns in space.

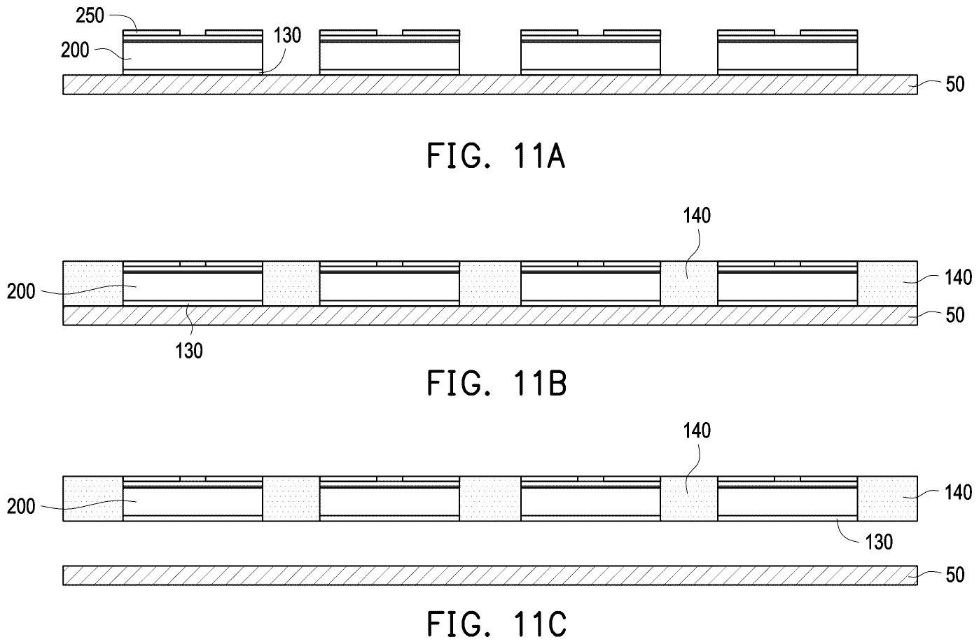

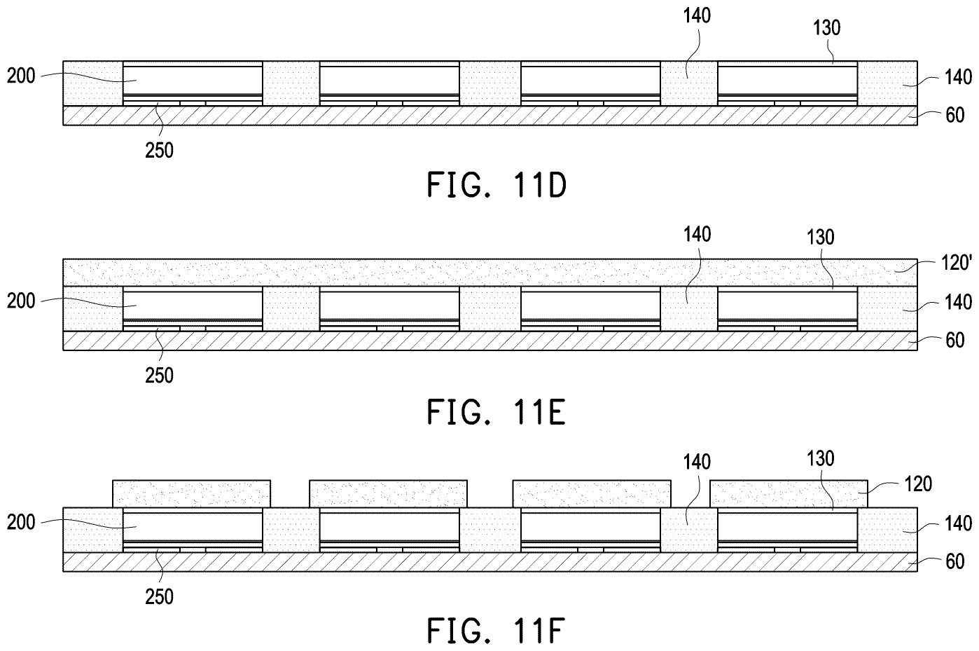

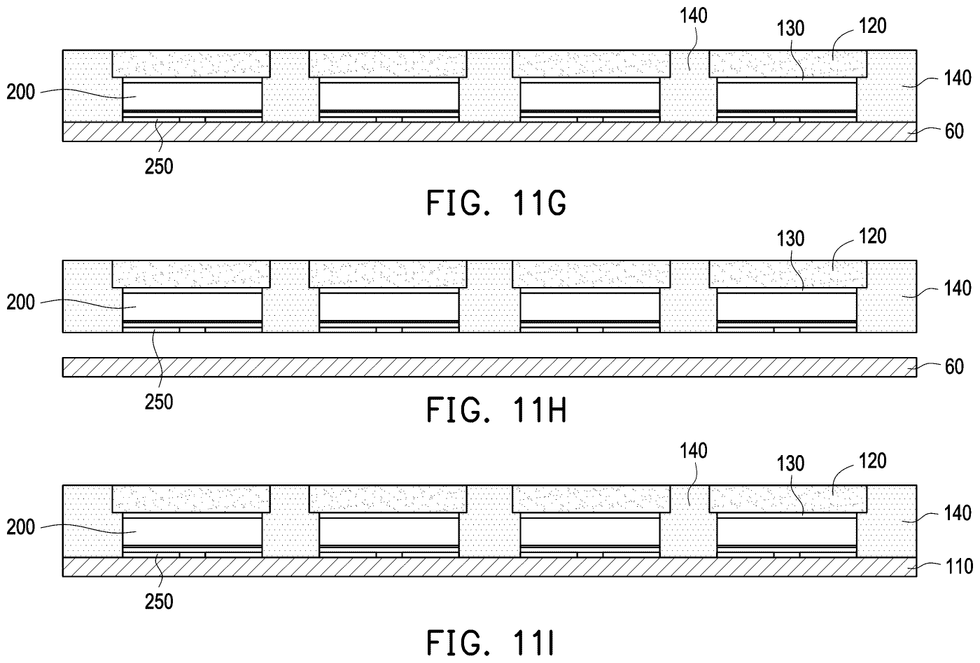

FIGS. 11A to 11I are cross-sectional schematic diagrams illustrating the process flow of a manufacturing method of a light-emitting diode structure according to an embodiment of the disclosure. Referring to FIGS. 11A to 11I, the manufacturing method of the light-emitting diode structure in this embodiment may be used to manufacture the light-emitting diode structures of the above embodiments. The following description takes the manufacturing of the light-emitting diode structure 100 in FIG. 1A as an example. The manufacturing method of the light-emitting diode structure in this embodiment includes the following steps. First, referring to FIG. 11A, a plurality of light-emitting diode chips 200 are provided, wherein each of the light-emitting diode chips 200 has an electrode 250, and a short-pass filter coating 130 is disposed on a side of the light-emitting diode chip 200 facing away from the electrode 250. The details of the light-emitting diode chip 200 and the short-pass filter coating 130 have been described in the above embodiments and will not be repeated here. Next, the light-emitting diode chips 200 are first disposed on a first temporary substrate 50, with the electrode 250 facing away from the first temporary substrate 50. Then, referring to FIG. 11B, a reflective layer 140 is filled in a gap between the light-emitting diode chips 200 and on a side surface of the light-emitting diode chips 200. Next, referring to FIG. 11C, the light-emitting diode chips 200, along with the reflective layer 140 and the short-pass filter coating 130, are separated from the first temporary substrate 50.

After that, as shown in FIG. 11D, the light-emitting diode chips 200, along with the reflective layer 140 and the short-pass filter coating 130, are disposed on a second temporary substrate 60, with the electrode 250 facing the second temporary substrate 60.

Next, as shown in FIG. 11E, the plurality of light-emitting diode chips 200 are covered with a wavelength conversion layer 120′. In this embodiment, the wavelength conversion layer 120′ also covers the reflective layer 140 and the short-pass filter coating 130. Then, in this embodiment, referring to FIG. 11F, the wavelength conversion layer 120′ is cut to form a plurality of separated wavelength conversion layers 120, which are respectively located on the short-pass filter coatings 130. These separated wavelength conversion layers 120 may be regarded as a plurality of separated wavelength conversion units respectively disposed on the light-emitting diode chips 200. Next, as shown in FIG. 11G, in this embodiment, the gaps between the plurality of wavelength conversion layers 120 after cutting are filled with the reflective layer 140. That is, after cutting the wavelength conversion layer 120′, the material of the reflective layer 140 is filled in the gaps between the wavelength conversion units and on the side surfaces of the wavelength conversion units to increase the height of the reflective layer 140. Afterward, referring to FIG. 11H, the light-emitting diode chips 200, along with the reflective layer 140 and the wavelength conversion layer 120, are separated from the second temporary substrate 60. Next, referring to FIG. 11I, the light-emitting diode chips 200, along with the reflective layer 140 and the wavelength conversion layer 120, are disposed on the substrate 110. This completes the fabrication of the light-emitting diode structure 100. The light-emitting diode structure manufactured by the manufacturing method of the light-emitting diode structure in this embodiment (e.g., the light-emitting diode structure 100) may achieve the same effects as those of the light-emitting diode structure 100 described in the above embodiments, which will not be repeated here.

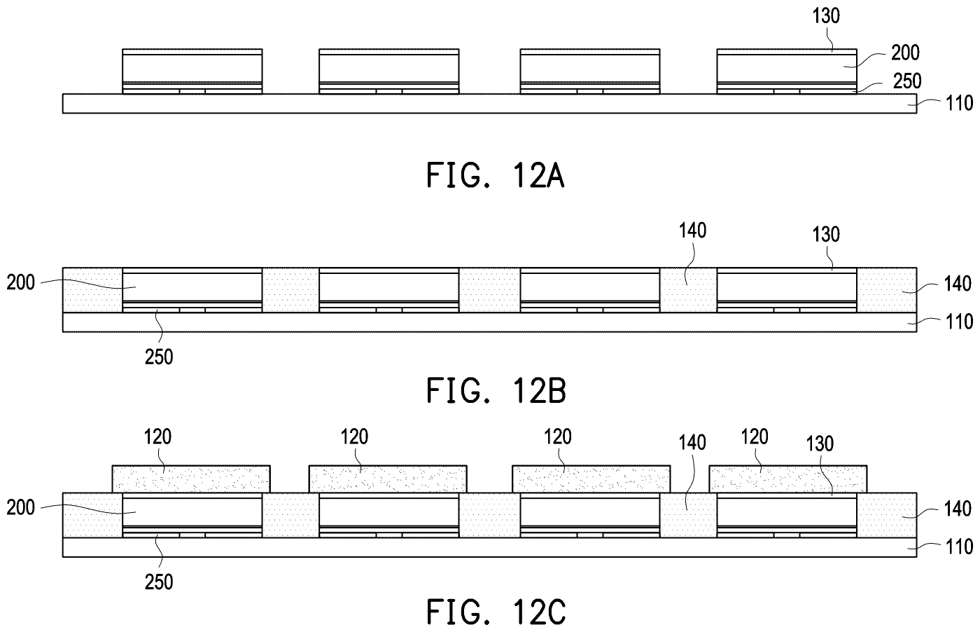

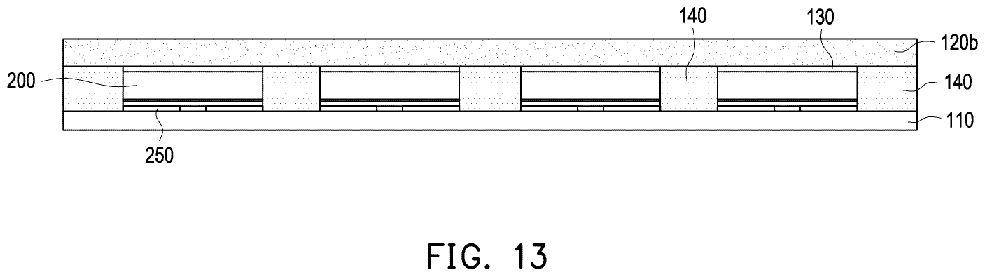

FIGS. 12A to 12C are cross-sectional schematic diagrams illustrating the process flow of a manufacturing method of a light-emitting diode structure according to another embodiment of the disclosure. Referring to FIGS. 12A to 12C, the manufacturing method of the light-emitting diode structure in this embodiment may be used to manufacture the light-emitting diode structures of the above embodiments. The following description takes the manufacturing of the light-emitting diode structure 100 in FIG. 1 as an example. The manufacturing method of the light-emitting diode structure in this embodiment includes the following steps. First, referring to FIG.

12A, a plurality of light-emitting diode chips 200 are provided, wherein each of the light-emitting diode chips 200 has an electrode 250, and a short-pass filter coating 130 is disposed on a side of the light-emitting diode chip 200 facing away from the electrode 250. The details of the light-emitting diode chip 200 and the short-pass filter coating 130 have been described in the above embodiments and will not be repeated here. Next, the light-emitting diode chips 200 are disposed on the substrate 110, with the electrode 250 facing the substrate 110. Then, referring to FIG. 12B, a reflective layer 140 is filled in a gap between the light-emitting diode chips 200 and on a side surface of the light-emitting diode chips 200. Afterward, referring to FIG. 12C, the light-emitting diode chips 200 are covered with a wavelength conversion layer 120. The method for forming the wavelength conversion layer 120 may be as shown in FIG. 11E, where a continuous wavelength conversion layer 120′ entirely covers the light-emitting diode chips 200, and then the wavelength conversion layer 120′ is cut into a plurality of separated wavelength conversion layers 120. Alternatively, the wavelength conversion layers 120 may be individually formed on the light-emitting diode chips 200. These separated wavelength conversion layers may be regarded as a plurality of separated wavelength conversion units, which respectively cover the light-emitting diode chips 200.

In an embodiment, after the step in FIG. 12C, a projection lens 160 (as shown in FIG. 9) may also be disposed above the light-emitting diode chips 200 to form a light-emitting diode structure 100d similar to FIG. 9.

FIG. 13 is a cross-sectional schematic diagram illustrating one step of a manufacturing method of a light-emitting diode structure according to yet another embodiment of the disclosure. Referring to FIG. 13, the manufacturing method of the light-emitting diode structure in this embodiment is similar to the manufacturing method of the light-emitting diode structure in FIGS. 12A to 12C, with the primary differences described as follows. The manufacturing method of the light-emitting diode structure in this embodiment proceeds with the steps in FIGS. 12A to 12B and then proceeds with the step shown in FIG. 13, where a continuous wavelength conversion layer 120b entirely covers the light-emitting diode chips 200 and the reflective layer 140 as a whole. Similarly, in the manufacturing method of the light-emitting diode structure in FIGS. 11A to 11I, the step of cutting the wavelength conversion layer 120′ as shown in FIG. 11F may be omitted. Instead, the continuous wavelength conversion layer 120′ may remain on the light-emitting diode chips 200 and the reflective layer 140. Then, the light-emitting diode chips 200, along with the reflective layer 140 and the wavelength conversion layer 120′, are separated from the second temporary substrate 60. After that, the light-emitting diode chips 200, along with the reflective layer 140 and the wavelength conversion layer 120′, are disposed on the substrate 110.

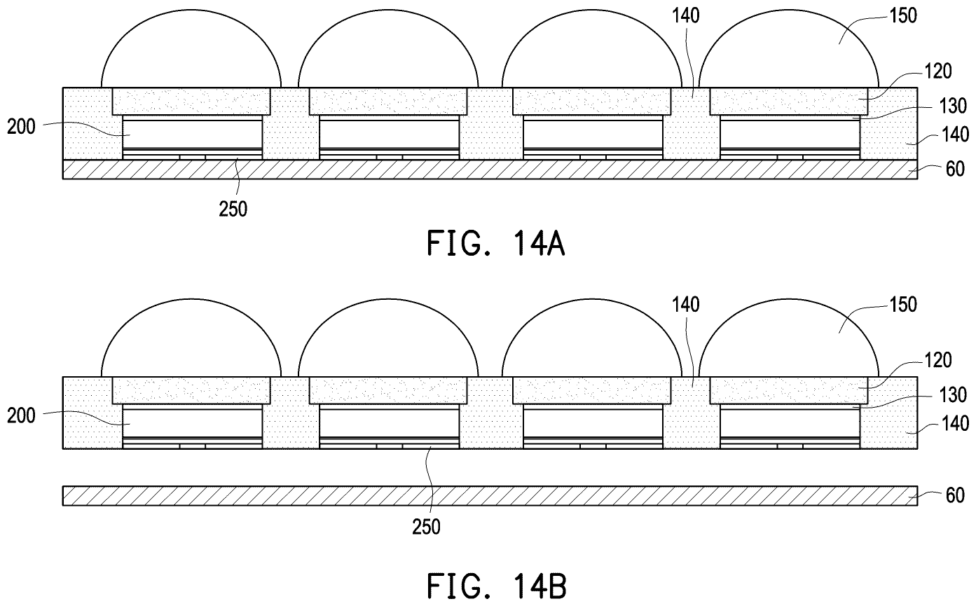

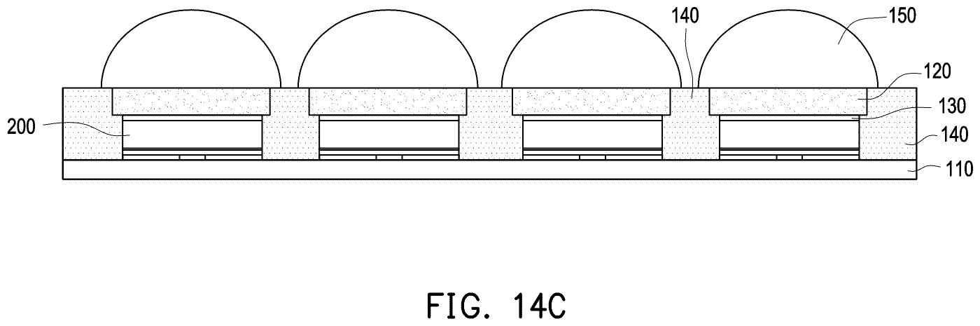

FIGS. 14A to 14C are cross-sectional schematic diagrams illustrating part of the process flow of a manufacturing method of a light-emitting diode structure according to still another embodiment of the disclosure. Referring to FIGS. 14A to 14C, the manufacturing method of the light-emitting diode structure in this embodiment is similar to the manufacturing method of the light-emitting diode structure in FIGS. 11A to 11I, with the primary differences described as follows. The manufacturing method of the light-emitting diode structure in this embodiment proceeds with the steps in FIGS. 11A to 11G and then proceeds with the step shown in FIG. 14A, where a plurality of lenses 150 are respectively formed on the wavelength conversion layers 120 on the light-emitting diode chips 200. Afterward, referring to FIG. 14B, the light-emitting diode chips 200, along with the reflective layer 140, the wavelength conversion layers 120, and the lenses 150, are separated from the second temporary substrate 60. Next, referring to FIG. 14C, the light-emitting diode chips 200, along with the reflective layer 140, the wavelength conversion layers 120, and the lenses 150, are disposed on the substrate 110. Similarly, in the manufacturing method of the light-emitting diode structure in FIGS. 12A to 12C, after the step in FIG. 12C, a plurality of lenses 150 may also be respectively formed on the wavelength conversion layers 120 on the light-emitting diode chips 200.

In summary, in the light-emitting diode structure and the manufacturing method thereof according to the embodiments of the disclosure, the short-pass filter coating allows the first light beam emitted by the light-emitting diode chip to pass through and reflects the second light beam from the wavelength conversion layer. As a result, the loss of the second light beam transmitted into the interior of the light-emitting diode chip may be effectively reduced, thereby improving the light efficiency of the light-emitting diode structure. Additionally, in the light-emitting diode structure and the manufacturing method thereof according to the embodiments of the disclosure, the reflective layer is filled in the gap between the plurality of light-emitting diode chips of the plurality of light-emitting diode units and is disposed on a side surface of the plurality of light-emitting diode chips to achieve integrated packaging of the light-emitting diode chips. This configuration reduces the spacing between adjacent light-emitting diode chips, resulting in a compact structure. Moreover, the manufacturing cost of the light-emitting diode structure may be effectively reduced.

Finally, it should be noted that the above embodiments are only used to illustrate the technical solutions of the disclosure and are not intended to limit the disclosure. Although the disclosure has been described in detail with reference to the foregoing embodiments, those skilled in the art should understand that modifications may still be made to the technical solutions described in the foregoing embodiments, or some or all of the technical features may be replaced with equivalents. These modifications or replacements do not cause the essence of the corresponding technical solutions to deviate from the scope of the technical solutions in the embodiments of the disclosure.

What is claimed is:

1. A light-emitting diode structure, comprising:
a substrate;
a plurality of light-emitting diode units, arranged in an array on the substrate, wherein each of the plurality of light-emitting diode units comprises:
a light-emitting diode chip, disposed on the substrate in a flip-chip manner and used to emit a first light beam;
a wavelength conversion layer, disposed on the light-emitting diode chip and used to convert a portion of the first light beam into a second light beam, wherein a wavelength of the first light beam is less than a wavelength of the second light beam;
a short-pass filter coating, disposed between the wavelength conversion layer and the light-emitting diode chip, wherein the short-pass filter coating allows the first light beam to pass through and reflects the second light beam; and
a reflective layer, filled in a gap between the plurality of light-emitting diode chips of the plurality of light-emitting diode units, and disposed on a side surface of the plurality of light-emitting diode chips.

2. The light-emitting diode structure according to claim 1, wherein the wavelength conversion layer is a phosphor layer or a quantum dot layer.

3. The light-emitting diode structure according to claim 1, wherein the short-pass filter coating is disposed on a side of the light-emitting diode chip away from the substrate.

4. The light-emitting diode structure according to claim 3, wherein the wavelength conversion layer is disposed on a side of the short-pass filter coating away from the substrate.

5. The light-emitting diode structure according to claim 4, wherein the reflective layer covers a side surface of the wavelength conversion layer.

6. The light-emitting diode structure according to claim 4, wherein the wavelength conversion layer covers a top surface of the reflective layer or is disposed on a portion of the top surface of the reflective layer.

7. The light-emitting diode structure according to claim 1, wherein the light-emitting diode chip comprises:
a growth substrate, wherein the short-pass filter coating is disposed on a surface of the growth substrate facing away from the substrate;
a first type semiconductor layer, disposed between the growth substrate and the substrate;
a light-emitting layer, disposed between the first type semiconductor layer and the substrate;
a second type semiconductor layer, disposed between the light-emitting layer and the substrate; and
an electrode, disposed between the second type semiconductor layer and the substrate, and electrically connected to the substrate.

8. The light-emitting diode structure according to claim 1, wherein the light-emitting diode unit further comprises a lens, disposed on the wavelength conversion layer.

9. The light-emitting diode structure according to claim 1, further comprising a projection lens, disposed above the plurality of light-emitting diode units.

10. The light-emitting diode structure according to claim 9, further comprising:
a driver, electrically connected to the plurality of light-emitting diode units and used to control the plurality of light-emitting diode units separately, wherein the driver is used to receive a control signal provided by a controller to adjust a different illuminance distribution of the plurality of light-emitting diode units projected into a space through the projection lens.

11. A manufacturing method of a light-emitting diode structure, comprising:
providing a plurality of light-emitting diode chips, wherein each of the plurality of light-emitting diode chips has an electrode, and a short-pass filter coating is disposed on a side of the light-emitting diode chip facing away from the electrode;
disposing the plurality of light-emitting diode chips on a first temporary substrate, with the electrode facing away from the first temporary substrate;
filling a reflective layer in a gap between the plurality of light-emitting diode chips and on a side surface of the plurality of light-emitting diode chips;
separating the plurality of light-emitting diode chips along with the reflective layer from the first temporary substrate;
disposing the plurality of light-emitting diode chips along with the reflective layer on a second temporary substrate, with the electrode facing the second temporary substrate;
covering the plurality of light-emitting diode chips with a wavelength conversion layer;
separating the plurality of light-emitting diode chips along with the reflective layer and the wavelength conversion layer from the second temporary substrate; and
disposing the plurality of light-emitting diode chips along with the reflective layer and the wavelength conversion layer on a substrate.

12. The manufacturing method of the light-emitting diode structure according to claim 11, further comprising:
after covering the plurality of light-emitting diode chips with the wavelength conversion layer, cutting the wavelength conversion layer corresponding to the plurality of light-emitting diode chips to respectively form a plurality of wavelength conversion units above the plurality of light-emitting diode chips.

13. The manufacturing method of the light-emitting diode structure according to claim 12, further comprising:
after cutting the wavelength conversion layer, filling a material of the reflective layer into a gap between the plurality of wavelength conversion units and on a side surface of the plurality of wavelength conversion units to increase a height of the reflective layer.

14. The manufacturing method of the light-emitting diode structure according to claim 11, wherein when disposing the plurality of light-emitting diode chips along with the reflective layer and the wavelength conversion layer on the substrate, the wavelength conversion layer covers an entire surface of the plurality of light-emitting diode chips and the reflective layer.

15. The manufacturing method of the light-emitting diode structure according to claim 11, further comprising:
respectively forming a plurality of lenses on the wavelength conversion layer on the plurality of light-emitting diode chips.

16. A manufacturing method of a light-emitting diode structure, comprising:
providing a plurality of light-emitting diode chips, wherein each of the plurality of light-emitting diode chips has an electrode, and a short-pass filter coating is disposed on a side of the light-emitting diode chip facing away from the electrode;
disposing the plurality of light-emitting diode chips on a substrate, with the electrode facing the substrate;
filling a reflective layer in a gap between the plurality of light-emitting diode chips and on a side surface of the plurality of light-emitting diode chips; and
covering the plurality of light-emitting diode chips with a wavelength conversion layer.

17. The manufacturing method of the light-emitting diode structure according to claim 16, wherein the wavelength conversion layer comprises a plurality of wavelength conversion units, separated from each other and respectively cover the plurality of light-emitting diode chips.

18. The manufacturing method of the light-emitting diode structure according to claim 16, wherein the wavelength conversion layer is continuous and covers an entire surface of the plurality of light-emitting diode chips and the reflective layer.

19. The manufacturing method of the light-emitting diode structure according to claim 16, further comprising:
respectively forming a plurality of lenses on the wavelength conversion layer on the plurality of light-emitting diode chips.

20. The manufacturing method of the light-emitting diode structure according to claim 16. further comprising:
disposing a projection lens above the plurality of light-emitting diode chips.
